(19) United States
(12) Patent Application Publication
(10) Pub. No.: US 2010/0127368 A1
(43) Pub. Date: May 27, 2010

(54) LEAD FRAME

(75) Inventor: Feng-Chun CHUNG, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: LINGSEN PRECISION INDUSTRIES, LTD., Taichung (TW)

(21) Appl. No.: 12/361,939

(22) Filed: Jan. 29, 2009

(30) Foreign Application Priority Data
Nov. 27, 2008 (TW) 97221269

(51) Int. Cl. H01L 23/495

(52) U.S. Cl. 257/676; 257/E23.037

(57) ABSTRACT

A lead frame includes a plurality of units arranged in a matrix manner. Each unit has an external frame defining an accommodation area, a die mount pad disposed in the accommodation area of the external frame, a plurality of leads connected with the external frame and arranged around the die mount pad, a short bar having two ends respectively electrically connected with the die mount pad and one of the leads, and a plurality of support bars each having a straight section connected with the external frame, and a continuous curved section connected with the die mount pad. By means of the continuous curved sections of the support bars, thermal deformation and/or displacement of the lead frame can be prevented.

### BACKGROUND OF THE INVENTION

1. Field of the Invention

The present invention relates generally to a lead frame, and more specifically to a lead frame that can prevent itself from thermal deformation during the wire bonding process.

2. Description of the Related Art

FIG. 1 shows a unit 10 of a lead frame according to a prior art. The unit 10 comprises an external frame 11, a plurality of leads 12 connected with the external frame 11, a die mount pad 13 for supporting a chip, and four support bars 14 connected with the external frame 11 and the die mount pad 13. In order to serve special needs of products, a short bar 15 is provided to connect the die mount pad 13 to one of the leads 12 for eliminating static electricity.

During the wire bonding process, the lead frame is attached to a heat block and then heated at about 200° C. Since the die mount pad 13 is restricted by the short bar 15 and the support bars 14 that are bridged between the external frame 11 and the die mount pad 13 have a straight shape without a thermal deformation-absorbing design, the thermal expansion stress concentrated in the unit 10 can't be released, causing displacement or deformation of the die mount pad 13. Under this circumstance, if the wire bonding process continues, some units may be unable to have wire bond connections correctly or a leakage of resin encapsulant may occur during the molding process that follows the wire bonding process due to the displacement or deformation of the die mount pad 13, resulting in decrease of the product yield.

### SUMMARY OF THE INVENTION

The present invention has been accomplished in view of the above-noted circumstances. It is one objective of the present invention to provide a lead frame, which provides a stretchable design to release the thermal expansion stress during the wire bonding process so as to increase the product yield.

To achieve this objective of the present invention, the lead frame comprises a plurality of units arranged in a matrix manner. The units each include an external frame defining an accommodation area, a die mount pad disposed in the accommodation area of the external frame, a plurality of leads connected with the external frame and arranged around the die mount pad, a short bar having two ends respectively electrically connected with the die mount pad and one of the leads, and a plurality of support bars each having a straight section connected with the external frame, and a continuous curved section connected with the die mount pad.

Accordingly, the lead frame of the present invention is capable of releasing the thermal expansion stress caused by the wire bonding process by means of the continuous curved sections of the support bars to prevent each of the units of the lead frame from thermal deformation and displacement, thereby raising the yield of the package.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic drawing of a unit of a lead frame according to a prior art;

FIG. 2 is a schematic drawing of a lead frame according to a first preferred embodiment of the present invention;

FIG. 3 is a schematic drawing of a unit of the lead frame according to the first preferred embodiment of the present invention, and

FIG. 4 is a schematic drawing of a unit of the lead frame according to a second preferred embodiment of the present invention.

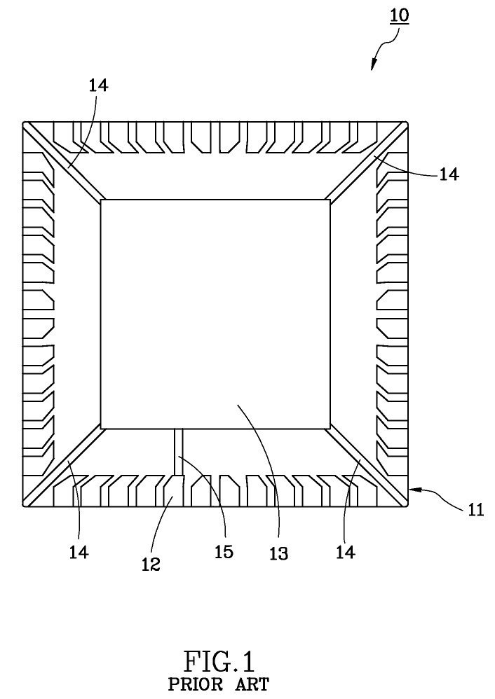

### DETAILED DESCRIPTION OF THE INVENTION

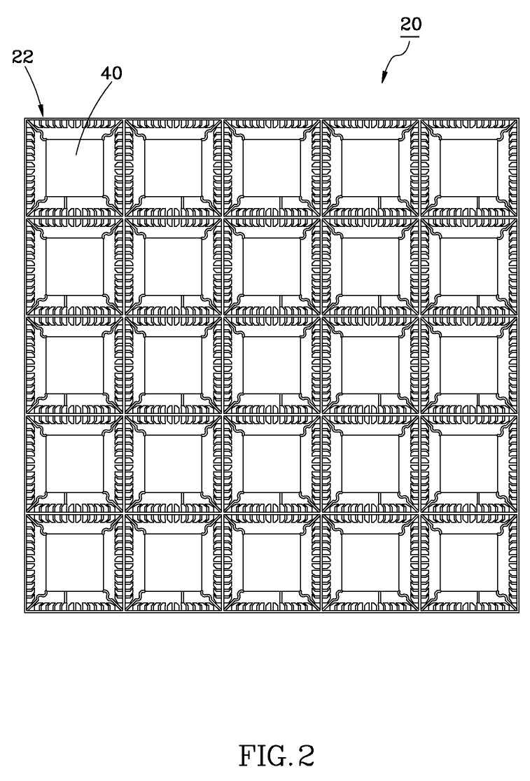

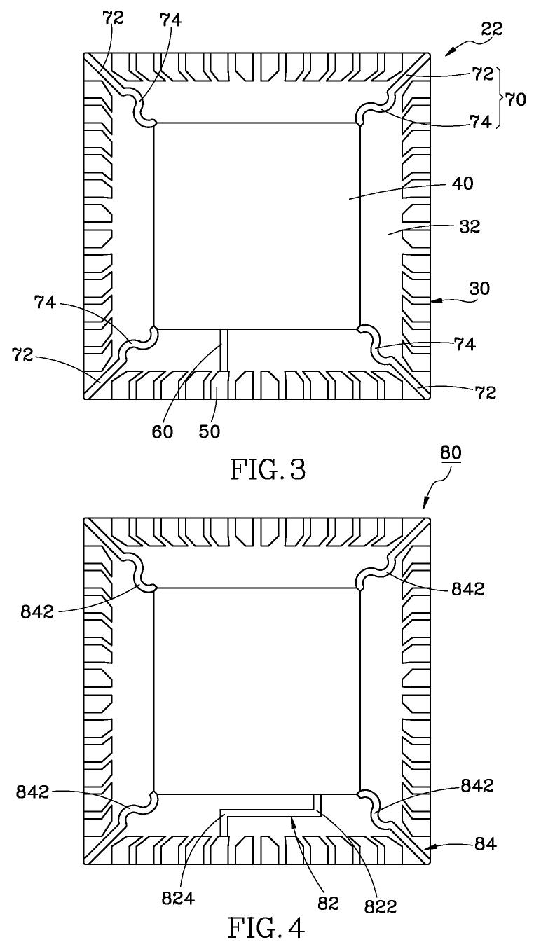

As shown in FIG. 2, a lead frame 20 in accordance with a first preferred embodiment of the present invention comprises a plurality of units 22 arranged in a matrix manner. As shown in FIG. 3, each of the units 22 includes an external frame 30, a die mount pad 40, a plurality of leads 50, a short bar 60 and four support bars 70.

The external frame 30 defines a square accommodation area 32.

The die mount pad 40 is disposed in the center of the accommodation area 32 for supporting a chip (not shown).

Each of the leads 50 is connected with the external frame 30 and arranged around the die mount pad 40.

The short bar 60 is a straight line, having two ends respectively electrically connected with a lateral side of the die mount pad 40 and one of the leads 50 to provide a grounding function.

The support bars 70 each have a straight section 72 and an S-shaped continuous curved section 74. The straight section 72 has a distal end connected with a corner of the external frame 30, and the continuous curved section 74 has a distal end connected with a corner of the die mount pad 40.

When the lead frame 20 of the present invention is attached to a heat block and heated during the wire bonding process, the thermal expansion stress induced in each of the units 22 can be absorbed and released through the continuous curved sections 74 of the support bars 70 that have a continuous change of curvature respectively. As a result, each of the units 22 of the lead frame 10 of the present invention will not deform or displace despite the existence of the short bar 60 during the wire bonding process, thereby enhancing the yield of the package.

It is to be mentioned that the short bar is not limited to a straight line. As shown in FIG. 4, a unit 80 of a lead frame in accordance with a second preferred embodiment of the present invention comprises a short bar 82 that has two turns 822 and 824 to form a curved shape, such as an N-shaped curve, for assisting the continuous curved sections 842 of the support bars 84 to release the thermal expansion stress generated in the lead frame.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A lead frame comprising:
a plurality of units arranged in a matrix manner, said units each comprising an external frame defining an accommodation area, a die mount pad disposed in said accommodation area of said external frame, a plurality of leads connected with said external frame and arranged around said die mount pad, a short bar having two ends respectively electrically connected with said die mount pad and one of said leads, and a plurality of support bars each having a straight section connected with said external frame, and a continuous curved section connected with said die mount pad.

2. The lead frame as claimed in claim 1, said continuous curved section of each of said support bars is S-shaped.

3. The lead frame as claimed in claim 1, wherein said short bar has two turns to form a curved shape.

4. The lead frame as claimed in claim 3, wherein said short bar is N-shaped.
